(19) United States
(12) Patent Application Publication
(10) Pub. No.: US 2007/0228379 A1
(43) Pub. Date: Oct. 4, 2007

(54) E-ink display panel and active device array substrate thereof

(75) Inventors: Yu-Chen Hsu, Hsinchu (TW); Chi-Ming Wu, Hsinchu (TW)

Correspondence Address: SHEEHAN PHINNEY BASS & GREEN, PA;c/o PETER NIEVES, 1000 ELM STREET, MANCHESTER, NH, 03105-3701, US

(73) Assignee: PRIME VIEW INTERNATIONAL CO., LTD., HSINCHU (TW)

(21) Appl. No.: 11/651,735

(22) Filed: Jan. 10, 2007

(30) Foreign Application Priority Data
Mar. 28, 2006 (TW) 95110655

(51) Int. Cl. H01L 29/04

(52) U.S. Cl. 257/72

(57) ABSTRACT

An E-ink display panel including an active device matrix substrate, an opposite substrate and a display medium is provided. The active device matrix substrate includes pixel structures disposed thereon, and each pixel structure includes a bottom-gate thin film transistor and a pixel electrode. The pixel electrode disposed on the dielectric layer covers a portion of a channel layer of the bottom-gate thin film transistor and is electrically connected to a drain of the bottom-gate thin film transistor. The opposite substrate is above the active device matrix substrate. The display medium is disposed between the active device matrix substrate and the opposite substrate.

### RELATED APPLICATIONS

The present application is based on, and claims priority from, Taiwan Application Serial Number 95110655, filed Mar. 28, 2006, the disclosure of which is hereby incorporated by reference herein in its entirety.

### BACKGROUND

1. Field of Invention

The present invention relates to a display panel. More particularly, the present invention relates to an E-ink display panel.

2. Description of Related Art

E-ink display panel was initially developed in 1970's. It is featured by a charged small ball with white color on one side and black color on the other side. The charged small ball rotates up and down to show different colors when the electrical field applied to small ball is changed. The second generation E-ink display panel, developed in 1990's, is featured by a microcapsule which substitutes the conventional charged ball. The microcapsule is filled by color oil and charged white particles. By varying external electrical field allows white particles to move up or down. White color will be shown when white particles are moving up (getting close to reader) and the color of oil will be shown when white particles are moving down (getting away from reader).

E-paper has featuring characteristics such as, high readability, low power consumption, flexibility, portability, etc. Therefore, the E-ink display panel has been the solution for PDA, cell phone, electronic reader, or any other information intensive and portable devices which require high readability in dynamic lighting environment.

Segment type display panel, an early product of E-paper, can only show alphanumeric or predefined symbols. As the growing development of related technique in recent years, E-paper driven by active matrix has been gradually considered. In order to obtain high aperture ratio expected in modern E-paper product, pixel electrodes are extended to cover thin film transistors, scan lines, and data lines of the active matrix in order to expand the area controlled by a pixel electrode and obtain high display quality. However, since pixel electrodes are right on the top of the channel layer of thin film transistor, a top-gate thin film transistor is conventionally used in order to prevent thin film transistor from being interfered by pixel electrode.

FIG. 1 is a cross-sectional diagram showing a conventional active device array substrate with top-gate thin film transistors. Active device array substrate 100 comprises a substrate 110, a top-gate thin film transistor 120, a passivation layer 130 and a pixel electrode 140. A top-gate thin film transistor 120 is disposed on substrate 110 and comprises a source 122a, a drain 122b, a channel layer 124, a gate dielectric layer 126 and a gate 128. The passivation layer 130 covers on the top-gate thin film transistor 120. A contact window 130a in the gate dielectric layer 126 and the passivation layer 130 partially exposes the source 122b. A pixel electrode 140 is on the top of the passivation layer 130 and electrically connected to the drain 122b via the contact window 130a. Furthermore, the whole pixel including the area on the top of the top-gate thin film transistor 120 is covered by the pixel electrode 140 to increase display quality provided by application of the active device array substrate 100.

Performance of thin film transistor is influenced by the pixel electrode mentioned above. The conventional method to solve such problem was to use top-gate thin film transistor when the method of using bottom-gate thin film transistor had not been disclosed.

### SUMMARY

An E-ink display panel comprising an active device array substrate, an opposite substrate and a display medium is provided. Active device array substrate comprises a substrate, a plurality of scan lines and data lines disposed on the substrate. A plurality of pixel structures are electrically connected to the data lines and the scan lines in order to be driven by the data lines and the scan lines. Each pixel structure comprises a bottom-gate thin film transistor and a pixel electrode. The bottom-gate thin film transistor comprises a gate, a source, a drain and a channel layer. The channel layer is formed between the gate and the source/drain. The gate is electrically connected to one of the scan lines and the source is connected to one of the data lines. The channel layer is partially covered by the pixel electrode, and the pixel electrode is electrically connected to the drain of the bottom-gate thin film transistor. The opposite substrate is formed on the active device array substrate. The display medium is formed between the active device array substrate and the opposite substrate.

According to an embodiment, the pixel structure comprises a dielectric layer, the dielectric layer containing a contact window is formed on bottom-gate thin film transistor to partially expose the bottom-gate thin film transistor.

According to another embodiment, the pixel electrode completely covers the corresponding bottom-gate thin film transistor.

According to another embodiment, the pixel electrode partially covers the neighboring data line.

According to another embodiment, the pixel electrode partially covers the neighboring scan line.

According to another embodiment, the pixel electrode partially covers the neighboring scan line and data line.

According to another embodiment, the opposite substrate comprises a substrate and a common electrode, the common electrode is formed between the substrate and the display medium.

According to another embodiment, the display medium comprises dark particles, shiny particles, and a transparent fluid. These dark particles and shiny particles have opposite polarity.

According to another embodiment, the display medium comprises ink particles, and each ink particle has one shiny side and one dark side and the two sides have opposite polarity.

Furthermore, an active device array substrate is provided in this invention. The structure of the active device array substrate is the same as the structure of the active device array substrate in the E-ink display panel mentioned above, so the detail description of the active device array substrate is omitted.

For the E-ink display panel described above, the pixel electrode on the active device array substrate covers thin film transistor and data line to improve display qu ality. However, a bottom-gate thin film transistor is used in this invention in order to be compatible to current product line of manufacturing bottom-gate thin film transistor. Conventional top-gate effect caused by pixel electrode can be avoided.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-sectional diagram showing a conventional active device array substrate with top-gate thin film transistors;

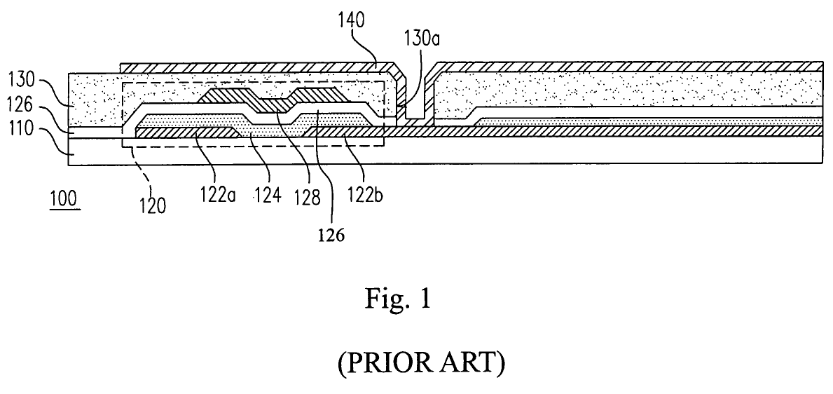

FIG. 2A is a top view of an active device array substrate of an E-ink display panel according to one embodiment of this invention,

FIG. 2B is a cross-sectional view along line A-A′ in FIG. 2A, and

FIG. 2C is a schematic view of an E-ink display panel, according to another embodiment of this invention.

### DETAILED DESCRIPTION

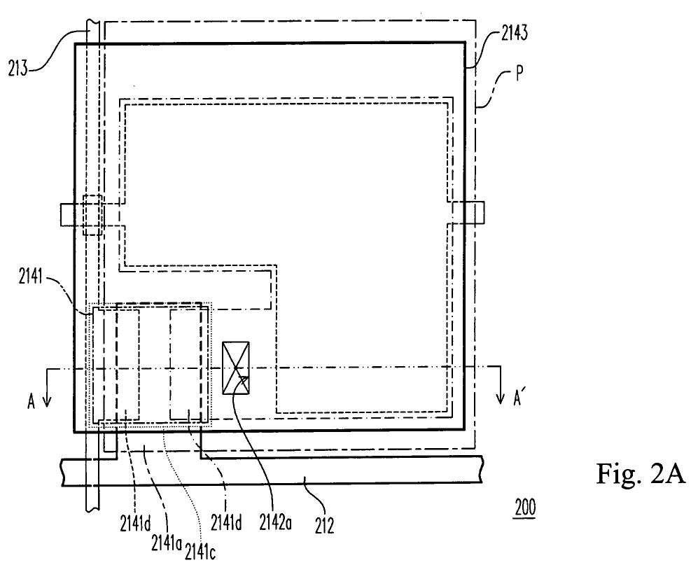

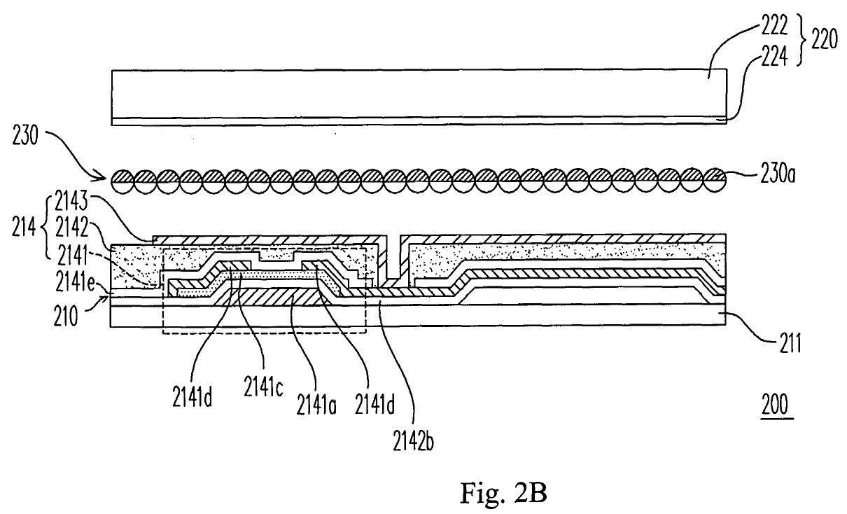

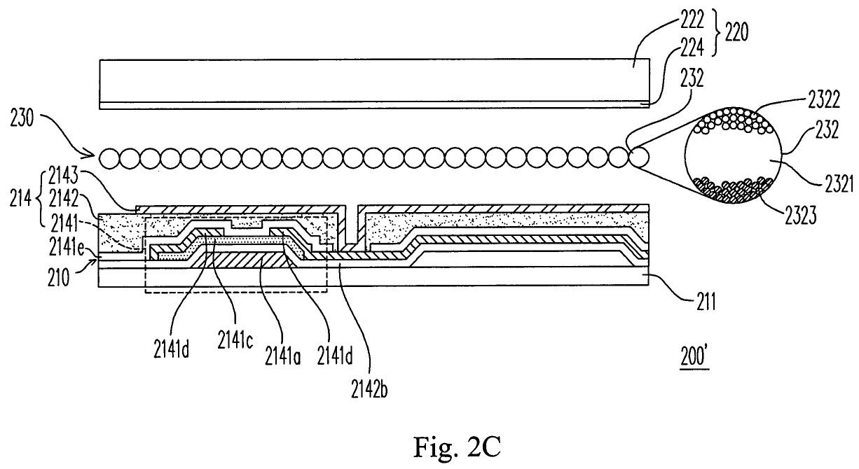

FIG. 2A is a top view of an active device array substrate of an E-ink display panel according to one embodiment of this invention; FIG. 2B is a cross-sectional view along line A-A′ in FIG. 2A. Only one pixel is illustrated in FIG. 2A. and FIG. 2B. Please refer to FIG. 2B, an E-ink display panel 200 comprises an active device array substrate 210, an opposite substrate 220 and a display medium 230. The structure of devices in the E-ink display panel 200 and correlation between each device will be illustrated by the help of figures.

Please refer to FIG. 2A and FIG. 2B, the active device array substrate 210 comprises a substrate 211, a plurality of scan lines 212, a plurality of data lines 213 and a plurality of pixel structures 214. The substrate 211 can be glass substrate, plastic substrate or other substrates. The scan lines 212 and data lines 213 are formed orthogonally on the substrate 211 in order to define a pixel area P with matrix type pixel arrangement. Pixel structure 214 is formed in the pixel area P and electrically connected to corresponding scan line 212 and data line 213 in order to be driven by scan line 212 and data line 213. Each pixel structure 214 comprises a bottom-gate thin film transistor 2141 and a pixel electrode 2143.

The bottom-gate thin film transistor 2141 comprises a gate 2141a, a gate dielectric layer 2141b, a channel layer 2141c and source/drain 2141d. The gate 2141a is formed on the substrate 211 and electrically connected to the scan line 212. The gate dielectric layer 2141b is formed on the substrate 211 and covers the gate 2141a. The channel layer 2141c is formed on the gate dielectric layer 2141b corresponded to the area where the gate 2141a is formed. The source/drain 2141d are formed on the channel layer 2141c. In this embodiment, the left source 2141d is electrically connected to the data line 213 and the right drain 2131d is electrically connected to the pixel electrode 2143 on the top of the bottom-gate thin film transistor 2141.

A dielectric layer 2142 with a contact window 2142a is formed on the bottom-gate thin film transistor 2141. The contact window 2142a allows the partial drain 2141d of the bottom-gate thin film transistor 2141 to be exposed. The dielectric layer 2142 covers whole bottom-gate thin film transistor 2141 to protect devices thereunder.

The pixel electrode 2143 is formed on the dielectric layer 2142 and covers partial channel layer 2141c. In this embodiment, the pixel electrode 2143 covers the whole bottom-gate thin film transistor 2141. The pixel electrode 2143 is electrically connected to the drain 2141d of the bottom-gate thin film transistor 2141 via the contact window 2142a of the dielectric layer 2142. The pixel electrode 2143 is usually made of Indium Tin Oxide or Indium Zinc Oxide. As shown in FIG. 2A, the pixel electrode 2143 covers partial data line 213 electrically connected to the pixel electrode 2143. The pixel electrode 2143 also covers partial neighboring scan line 212, or covers neighboring scan line 212 and data line 213.

Please refer to FIG. 2B, opposite substrate 220 is formed at the area corresponded to where the active device array substrate 210 is located. The opposite substrate 220 comprises a substrate 222 and a common electrode 224 formed on the substrate 222. The common electrode 224 can be a transparent conducting layer. A display medium 230 is formed between the active device array substrate 210 and the opposite substrate 220. The display medium 230 is, at least, bistable. Therefore, image signal can still remain even if the signal source has been removed after renewing the image.

In this embodiment, the display medium 230 comprises a plurality of ink particles 230a. Each ink particle 230a has one shiny side and one dark side and the two sides have opposite polarity. When the electric field between the pixel electrode 2143 and the common electrode 224 is changed, ink particles 230a of the display medium 230 will be driven to display images on E-ink display panel.

The display medium 230 is not necessary to be those mentioned above. FIG. 2C is a schematic view of an E-ink display panel, according to another embodiment of this invention. Please refer to FIG. 2C, the display medium 230 in this embodiment comprises dark particles 2323, shiny particles 2322 and a transparent fluid 2321. The dark particles 2323 and the shiny particles 2322 have opposite polarity. When the electric field between the pixel electrode 2143 and the common electrode 224 is changed, the dark particles 2323 and the shiny particles 2322 will move up or down according to the direction of electric field to display required image. In a further embodiment, the dark particles 2323, the shiny particles 2322 and the transparent fluid 2321 can be surrounded by microcapsules 232. In another embodiment, the dark particles 2323, the shiny particles 2322 and the transparent fluid 2321 are placed in a microcup. In yet another embodiment, the dark particles 2323, the shiny particles 2322 and the transparent fluid 2321 are not confined by lateral structure and able to move freely in the active area. In other embodiments, the dark particles 2323, the shiny particles 2322 and the transparent fluid 2321 can be disposed to any type of structure. Therefore, the display medium 230 is not limited in any specific form as described above.

Accordingly, the E-ink display panel is featured by the pixel electrode covering the thin film transistor underneath for improving display quality. The bottom-gate thin film transistor is used in this invention in order to be compatible to current product line of manufacturing bottom-gate thin film transistor and the conventional top-gate effect caused by voltage applied to pixel electrode can be avoided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An E-ink display panel, comprising:
an active device array substrate, comprising:
a substrate;
a plurality of scan lines and data lines on the substrate;
a plurality of pixel structures electrically connected to the data lines and the scan lines to be driven by the data lines and the scan lines, each of the pixel structure comprises:
a bottom-gate thin film transistor comprises a gate, a gate dielectric layer, a channel layer, and a source and a drain from bottom to top, wherein the gate is electrically connected to one of the scan line and the source is connected to the data line; and
a pixel electrode partially covering the channel layer and electrically connected to the drain of the bottom-gate thin film transistor;
an opposite substrate on the active device array substrate; and
a display medium between active device array substrate and the opposite substrate.

2. The E-ink display panel of claim 1, further comprising a dielectric layer, having a contact window therein to expose the drain, on the bottom-gate thin film transistor.

3. The E-ink display panel of claim 1, wherein the pixel electrode completely covers the corresponding bottom-gate thin film transistor.

4. The E-ink display panel of claim 1, wherein the pixel electrode partially covers the neighboring data line.

5. The E-ink display panel of claim 1, wherein the pixel electrode partially covers the neighboring scan line.

6. The E-ink display panel of claim 1, wherein the pixel electrode partially covers the neighboring scan line and data line.

7. The E-ink display panel of claim 1, wherein the opposite substrate comprises:
a substrate; and
a common electrode between the substrate and display medium.

8. The E-ink display panel of claim 1, wherein the display medium comprises:
a plurality of dark particles;
a plurality of shiny particles, the dark particles and the shiny particles having opposite polarity; and
a transparent fluid.

9. The E-ink display panel of claim 1, wherein the display medium comprises a plurality of ink particles and each of the ink particles has one shiny side and one dark side having opposite polarity.

10. An active device array substrate, comprising:
a substrate;
a plurality of scan lines and data lines on the substrate; and
a plurality of pixel structures on the substrate, each of the pixel structure comprises:
a bottom-gate thin film transistor (TFT), wherein a gate of the bottom-gate TFT is electrically connected to one of the scan lines and a source of the bottom-gate TFT is electrically connected to one of the data lines; and
a pixel electrode covering the channel layer partially and electrically connected to the drain of the bottom-gate thin film transistor.

11. The active device array substrate of claim 10, further comprising a dielectric layer, having a contact window therein to expose a drain of the bottom-gate TFT, on the bottom-gate TFT.

12. The active device array substrate of claim 10, wherein the pixel electrode completely covers the corresponding bottom-gate thin film transistor.

13. The active device array substrate of claim 10, wherein the pixel electrode partially covers the neighboring data line.

14. The active device array substrate of claim 10, wherein the pixel electrode partially covers the neighboring scan line.

15. The active device array substrate of claim 10, wherein the pixel electrode partially covers the neighboring scan line and data line.
